(19) United States
(12) Patent Application Publication
(10) Pub. No.: US 2026/0181829 A1
(43) Pub. Date: Jun. 25, 2026

(54) HEAT DISSIPATION ASSEMBLY, MOTHERBOARD MODULE AND ELECTRONIC DEVICE

(71) Applicant: Wiwynn Corporation, New Taipei City (TW)

(72) Inventors: Cheng-An Chen, New Taipei City (TW); Yi Cheng, New Taipei City (TW)

(21) Appl. No.: 19/295,914

(22) Filed: Aug. 11, 2025

(30) Foreign Application Priority Data
Dec. 20, 2024 (TW) 113149897

(51) Int. Cl. H05K 7/20; G06F 1/20

(52) U.S. Cl. CPC H05K 7/20327; G06F 1/206

(57) ABSTRACT

A heat dissipation assembly is configured to be thermally coupled to a first heat source and a second heat source which has a thermal design power greater than a thermal design power of the first heat source. The heat dissipation assembly includes a heat exchanger and a cold plate. The heat exchanger is configured to be thermally coupled to the first heat source and receive a coolant, such that the coolant absorbs heat generated by the first heat source so as to have temperature increase. The cold plate is configured to be thermally coupled to the second heat source, and the cold plate is in fluid communication with the heat exchanger for receiving the coolant from the heat exchanger, such that the coolant absorbs heat generated by the second heat source so as to vaporize.

### CROSS-REFERENCE TO RELATED APPLICATIONS

This non-provisional application claims priority under 35 U.S.C. § 119(a) on Patent Application No(s). 113149897 filed in Taiwan, R.O.C. on Dec. 20, 2024, the entire contents of which are hereby incorporated by reference.

### TECHNICAL FIELD

The disclosure relates to a heat dissipation assembly, a motherboard module and an electronic device.

### BACKGROUND

Currently, two-phase cold plates adopt the pool boiling method for dissipating heat from high-power chips. When a high-power chip starts operating, if the temperature of the coolant entering into the cold plate is too low, it must first be heated to its boiling point before undergoing a phase change to remove the heat generated by the chip. This may cause the chip's temperature to be too high during an initial stage of the operation. Therefore, how to solve the aforementioned issue is one of the topics in this field.

### SUMMARY

One embodiment of the disclosure provides a heat dissipation assembly. The heat dissipation assembly is configured to be thermally coupled to a first heat source and a second heat source which has a thermal design power greater than a thermal design power of the first heat source. The heat dissipation assembly includes a heat exchanger and a cold plate. The heat exchanger is configured to be thermally coupled to the first heat source and receive a coolant, such that the coolant absorbs heat generated by the first heat source so as to have temperature increase. The cold plate is configured to be thermally coupled to the second heat source, and the cold plate is in fluid communication with the heat exchanger for receiving the coolant from the heat exchanger, such that the coolant absorbs heat generated by the second heat source so as to vaporize.

Another embodiment of the disclosure provides a motherboard module. The motherboard module includes a motherboard and a heat dissipation assembly. The motherboard includes a first heat source and a second heat source which has a thermal design power greater than a thermal design power of the first heat source. The heat dissipation assembly includes a heat exchanger and a cold plate. The heat exchanger is configured to be thermally coupled to the first heat source and receive a coolant, such that the coolant absorbs heat generated by the first heat source so as to have temperature increase. The cold plate is configured to be thermally coupled to the second heat source, and the cold plate is in fluid communication with the heat exchanger for receiving the coolant from the heat exchanger, such that the coolant absorbs heat generated by the second heat source so as to vaporize.

Still another embodiment of the disclosure provides an electronic device. The electronic device includes a coolant distributing device and a motherboard module. The coolant distributing device is configured to output a coolant. The motherboard module includes a motherboard and a heat dissipation assembly. The motherboard includes a first heat source and a second heat source which has a thermal design power greater than a thermal design power of the first heat source. The heat dissipation assembly includes a heat exchanger and a cold plate. The heat exchanger is configured to be thermally coupled to the first heat source and in fluid communication with the coolant distributing device, and the heat exchanger is configured to receive the coolant, such that the coolant absorbs heat generated by the first heat source so as to have temperature increase. The cold plate is configured to be thermally coupled to the second heat source, and the cold plate is in fluid communication with the heat exchanger and the coolant distributing device, and the cold plate is configured to receive the coolant from the heat exchanger, such that the coolant absorbs heat generated by the second heat source so as to vaporize, and the vaporized coolant flows back to the coolant distributing device.

### BRIEF DESCRIPTION OF THE DRAWINGS

The present disclosure will become better understood from the detailed description given herein below and the accompanying drawings which are given by way of illustration only and thus are not intending to limit the present disclosure and wherein:

FIG. 1 shows a schematic view of an electronic device of one embodiment of the disclosure;

FIG. 2 shows a schematic view of a motherboard module of one embodiment of the disclosure;

FIG. 3 shows a schematic view of a motherboard module of one embodiment of the disclosure;

FIG. 4 shows a schematic view of a heat exchanger of one embodiment of the disclosure;

FIG. 5 shows a schematic view of a heat exchanger of one embodiment of the disclosure; and

FIG. 6 shows a schematic view of a heat exchanger of one embodiment of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the present disclosure, such as technical and scientific terms, have its own meanings and can be comprehended by those skilled in the art, unless the terms are additionally defined in the present disclosure. That is, the terms used in the following paragraphs should be read on the meaning commonly used in the related fields and will not be overly explained, unless the terms have a specific meaning in the present disclosure.

In the following paragraphs, the term “fluid communication” represents that fluid can flow between two objects or components.

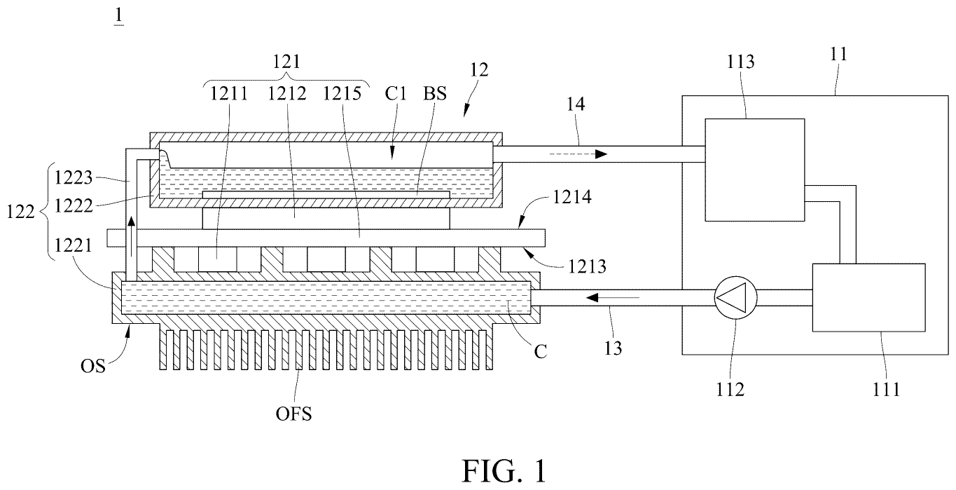

Referring to FIG. 1, FIG. 1 shows a schematic view of an electronic device 1 of one embodiment of the disclosure.

The electronic device 1 includes a coolant distributing device 11 and a motherboard module 12. The coolant distributing device 11 is configured to output a coolant C. The motherboard module 12 includes a motherboard 121 and a heat dissipation assembly 122. The motherboard 121 includes a first heat source 1211 and a second heat source 1212 which has a thermal design power greater than a thermal design power of the first heat source 1211. The heat dissipation assembly 122 includes a heat exchanger 1221 and a cold plate 1222. The heat exchanger 1221 is configured to be thermally coupled to the first heat source 1211 and in fluid communication with the coolant distributing device 11. The heat exchanger 1221 is configured to receive the coolant C, such that the coolant C flowing into the heat exchanger 1221 absorbs heat generated by the first heat source 1211 so as to have temperature increase. The cold plate 1222 is configured to be thermally coupled to the second heat source 1212, and the cold plate 1222 is in fluid communication with the heat exchanger 1221 and the coolant distributing device 11, and the cold plate 1222 is configured to receive the coolant C from the heat exchanger 1221, such that the coolant C absorbs heat generated by the second heat source 1212 so as to vaporize, and the vaporized coolant C flows back to the coolant distributing device 11.

In some embodiments, the electronic device 1 may further include a liquid pipe 13 and a gas pipe 14, and the coolant distributing device 11 may include a container 111, a pump 112 and a condenser 113. The container 111, the pump 112, the liquid pipe 13, the heat exchanger 1221, the cold plate 1222, the gas pipe 14 and the condenser 113 are sequentially connected to one another so as to from a circulation loop for the coolant, where the condenser 113, the container 111 and the pump 112 are in fluid communication with one another via pipes.

In some embodiments, the motherboard 121 may further include a circuit board 1215. The circuit board 1215 has a first surface 1213 and a second surface 1214 located opposite to each other. The first heat source 1211 and the second heat source 1212 are respectively disposed on the first surface 1213 and the second surface 1214 of the circuit board 1215; that is, the first heat source 1211 and the second heat source 1212 are respectively disposed at two opposite sides of the circuit board 1215. In addition, the heat dissipation assembly 122 may further include a connection pipe 1223. The connection pipe 1223 penetrates through the motherboard 121, and the cold plate 1222 thermally coupled to the second heat source 1212 is in fluid communication with the heat exchanger 1221 thermally coupled to the first heat source 1211 via the connection pipe 1223.

Note that the connection pipe 1223 is not restricted to penetrating through the motherboard 121. In some other embodiments, the connection pipe may bypass the motherboard; that is, the connection pipe may extend and pass by the edge of the motherboard and connect to the heat exchanger and the cold plate.

In some embodiments, the first heat source 1211 includes at least one of a voltage regulator chip, a network communication chip and a retimer chip. The second heat source 1212 includes at least one of a CPU and a GPU.

In some embodiments, the heat exchanger 1221 has an outer surface OS and an outer fin structure OFS. The outer fin structure OFS is disposed on the outer surface OS. The electronic device 1 may include a fan (not shown), and an airflow generated by the fan can pass by the outer fin structure OFS of the heat exchanger 1221 so as to remove heat generated by the first heat source 1211.

In some embodiments, the cold plate 1222 has a two-phase fluid chamber C1 and a boiling enhancement structure BS. The boiling enhancement structure BS is located in the two-phase fluid chamber C1. The boiling enhancement structure BS is configured to contact the coolant C. The boiling enhancement structure BS is to increase bubble nucleation sites, produce more boiling bubbles per unit time and increase the contact area with the coolant C. Although the boiling enhancement structure BS shown in FIG. 1 is simplified to a sheet, the boiling enhancement structure BS referred in the disclosure may actually include at least one of metal mesh structure, sheet-shaped fin structure, pin fin structure or sintered metal structure.

Then, the following descriptions will introduce the flowing process of the coolant C in the circulation loop. During the operation of the pump 112, the coolant C flows into the heat exchanger 1221 through the liquid pipe 13 and absorbs heat generated by the first heat source 1211 so as to have temperature increase. Next, the coolant C flows into the cold plate 1222 through the connection pipe 1223 and absorbs heat generated by the second heat source 1212 so as to vaporize. The gas coolant C flows into the condenser 113 through the gas pipe 14, and is condensed into the liquid coolant C. Then, the liquid coolant C flows back to the container 111 and is stored in the container 111.

In the electronic device 1, the heat exchanger 1221 is thermally coupled to the first heat source 1211 and receives the coolant C, the cold plate 1222 is thermally coupled to the second heat source 1212, which has a higher thermal design power than the first heat source 1211, and the cold plate 1222 is in fluid communication with the heat exchanger 1221 to receive the coolant C from it. With this configuration, before the coolant C flows into the cold plate 1222, it first passes through the heat exchanger 1221 and is preheated. As a result, the coolant C flowing out of the heat exchanger 1221 can maintain a certain temperature (e.g., close to the boiling point). Thus, when the coolant C enters into the cold plate 1222, it may undergo phase change immediately, effectively removing the heat generated by the second heat source 1212. This prevents the issue where, during the initial operation of the second heat source 1212, the coolant C is too cold to undergo an immediate phase change and thus hinder effective heat dissipation from the second heat source 1212.

Note that the first heat source 1211 and the second heat source 1212 of the motherboard 121 are not restricted to being respectively located at the first surface 1213 and the second surface 1214 of the circuit board 1215.

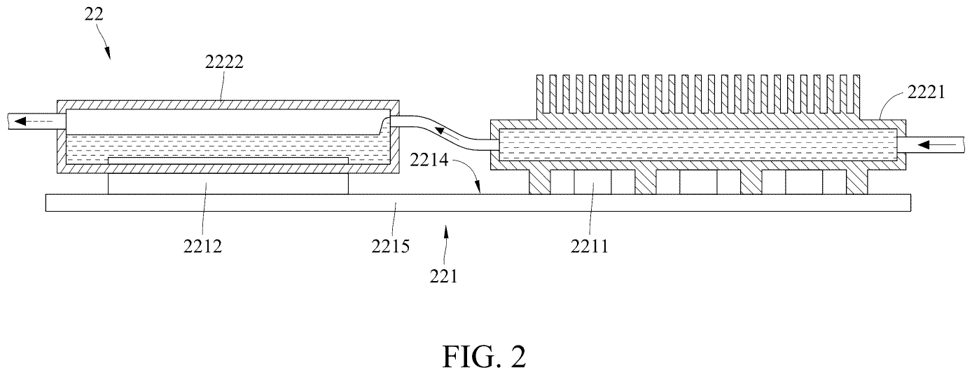

For example, FIG. 2 shows a schematic view of a motherboard module 22 of one embodiment of the disclosure, and the motherboard module 22 of this embodiment can replace the motherboard module 12 shown in FIG. 1. The motherboard module 22 of this embodiment is similar to the motherboard module 12 of the previous embodiment, and thus the following paragraph merely introduces the difference between them while the same part between them will not be repeatedly introduced hereinafter.

In some embodiments, a first heat source 2211 and a second heat source 2212 are disposed on a second surface 2214 of a circuit board 2215 of a motherboard 221; that is, the first heat source 2211 and the second heat source 2212 are disposed on a same side of the circuit board 2215. A heat exchanger 2221 thermally coupled to the first heat source 2211 may be the similar to the heat exchanger 1221 shown in FIG. 1, and a cold plate 2222 thermally coupled to the second heat source 2212 may be similar to the cold plate 1222 shown in FIG. 1.

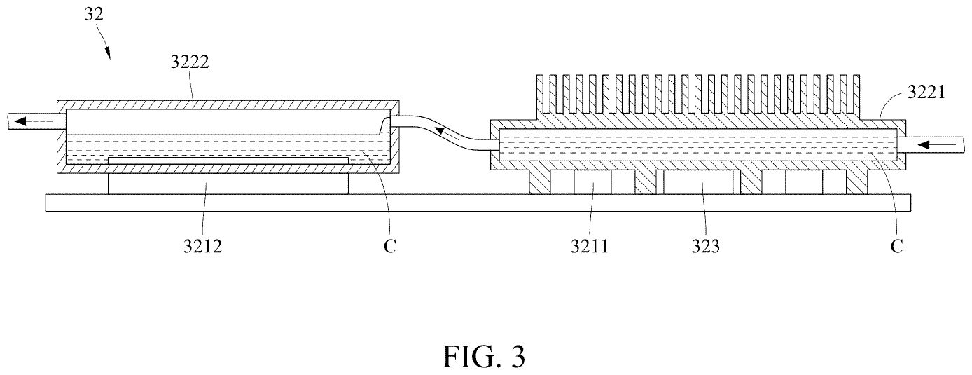

Then, referring to FIG. 3, FIG. 3 shows a schematic view of a motherboard module 32 of one embodiment of the disclosure, and the motherboard module 32 of this embodiment can replace the motherboard module 12 shown in FIG. 1. The motherboard module 32 of this embodiment is similar to the motherboard module 12 of the previous embodiment, and thus the following paragraphs merely introduce the difference between them while the same part between them will not be repeatedly introduced hereinafter.

The motherboard module 32 may further include a heater 323, the heater 323 is different from the first heat source 3211 and the second heat source 3212, and the heat exchanger 3221 is thermally coupled to the heater 323.

In some embodiments, the heater 323 is configured to heat the coolant C flowing into a heat exchanger 3221 when the coolant C does not reach a predetermined temperature, and stop heating the coolant C flowing into the heat exchanger 3221 when the coolant C reaches the predetermined temperature.

For example, a controller in the electronic device can obtain the temperature of the coolant C flowing into the heat exchanger 3221 via a temperature sensor. The controller can drive the heater 323 to heat the coolant C flowing into the heat exchanger 3221 when the coolant C does not reach the predetermined temperature and drive the heater 323 to stop heating the coolant C when the coolant C reaches the predetermined temperature. As a result, the temperature of the coolant C flowing into the cold plate 3222 from the heat exchanger 3221 can approach to the boiling point as close as possible, such that the coolant C can undergo phase change immediately after entering into the cold plate 3222, thereby effectively removing the heat generated by the second heat source 3212.

In some embodiments, the heater 323 is configured to heat the coolant C flowing into the heat exchanger 3221 when the second heat source 3212 does not reach a predetermined temperature, and stop heating the coolant C flowing into the heat exchanger 3221 when the second heat source 3212 reaches the predetermined temperature. In some embodiments, a controller in the electronic device can obtain the temperature of the second heat source 3212 via a temperature sensor.

For example, after the electronic device is powered on and the second heat source 3212 is not yet under load, the controller detects the temperature change of the second heat source 3212 via a temperature sensor to indirectly determine the temperature of the coolant C in the cold plate 3222. Assuming that the temperature of the second heat source 3212 rises by 10 degrees while it is still unloaded, it indicates that the coolant C in the cold plate 3222 causes the temperature of the second heat source 3212 to increases, and the temperature of the coolant C is sufficiently high. This ensures that once the second heat source 3212 starts loading, the coolant C can immediately undergo a phase change and effectively remove heat generated by the second heat source 3212. In other words, the second heat source 3212 can now begin operation with its heat efficiently removed by the coolant C. In contrast, assuming that the temperature of the second heat source 3212 does not rise by 10 degrees in its unloaded state, it indicates that the coolant C in the cold plate 3222 is not warm enough to undergo an immediate phase change when the second heat source 3212 starts loading. In this case, the controller activates the heater 323 to heat the coolant C in the heat exchanger 3221, allowing the heated coolant C to flow into the cold plate 3222. Once the temperature of the second heat source 3212 increases by 10 degrees due to the heated coolant C, the controller stops the operation of the heater 323 to save energy and allows the second heat source 3212 to begin loading.

Then, the following paragraphs will introduce heat exchangers of other embodiments. The heat exchangers of these embodiments described later can replace the heat changers in FIGS. 1 to 3.

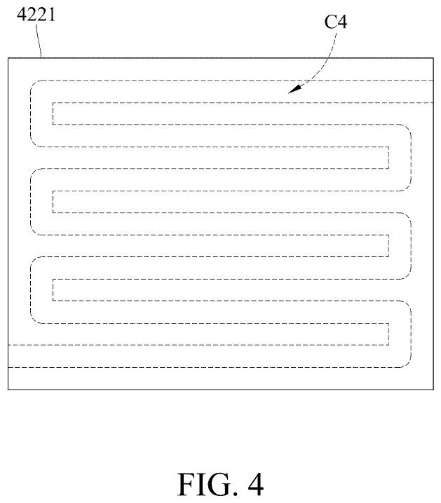

Referring to FIG. 4, FIG. 4 shows a schematic view of a heat exchanger 4221 of one embodiment of the disclosure. In some embodiments, the heat exchanger 4221 has a fluid channel C4, and the fluid channel C4 is in a wavy shape to improve the heat exchange efficiency between the heat exchanger 4221 and the coolant.

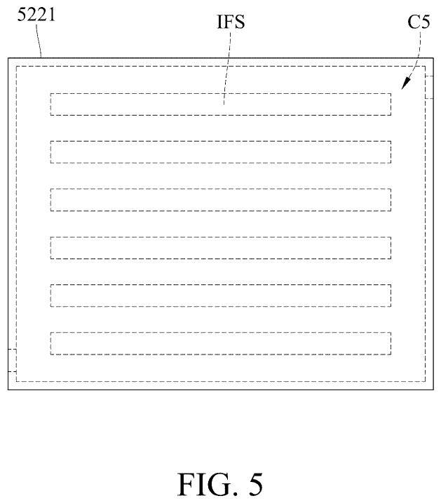

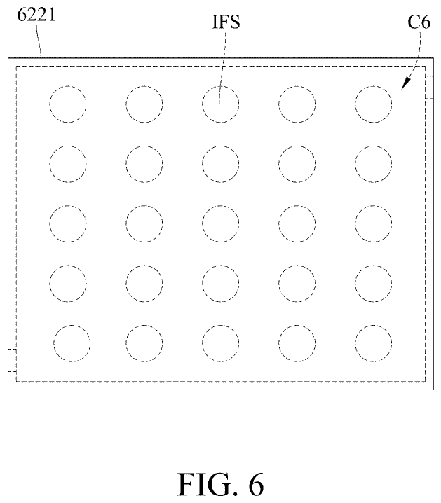

Note that the inner structure of the heat exchanger is not restricted to being the wavy channel. In some embodiments, the heat exchanger may have a liquid chamber and an inner fin structure, and the inner fin structure is located in the liquid chamber. For example, referring to FIG. 5, FIG. 5 shows a schematic view of a heat exchanger 5221 of one embodiment of the disclosure. An inner fin structure IFS in a liquid chamber C5 of the heat exchanger 5221 is in a sheet shape. Alternatively, referring to FIG. 6, FIG. 6 shows a schematic view of a heat exchanger 6221 of one embodiment of the disclosure. An inner fin structure IFS in a liquid chamber C6 of the heat exchanger 6221 is in a pillar shape or a pin shape.

According to the heat dissipation assemblies, the motherboard modules and the electronic device as discussed in the above embodiments, the heat exchanger is thermally coupled to the first heat source and receives the coolant, the cold plate is thermally coupled to the second heat source, which has a higher thermal design power than the first heat source, and the cold plate is in fluid communication with the heat exchanger to receive the coolant from it. With this configuration, before the coolant flows into the cold plate, it first passes through the heat exchanger and is preheated. As a result, the coolant flowing out of the heat exchanger can maintain a certain temperature (e.g., close to the boiling point). Thus, when the coolant enters into the cold plate, it can undergo phase change immediately, effectively removing the heat generated by the second heat source. This prevents the issue where, during the initial operation of the second heat source, the coolant C is too cold to undergo an immediate phase change and thus hinder effective heat dissipation from the second heat source.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. A heat dissipation assembly, configured to be thermally coupled to a first heat source and a second heat source which has a thermal design power greater than a thermal design power of the first heat source, the heat dissipation assembly comprising:
a heat exchanger, configured to be thermally coupled to the first heat source and receive a coolant, such that the coolant absorbs heat generated by the first heat source so as to have temperature increase; and
a cold plate, configured to be thermally coupled to the second heat source, wherein the cold plate is in fluid communication with the heat exchanger for receiving the coolant from the heat exchanger, such that the coolant absorbs heat generated by the second heat source so as to vaporize.

2. The heat dissipation assembly according to claim 1, wherein the cold plate has a two-phase fluid chamber and a boiling enhancement structure, and the boiling enhancement structure is located in the two-phase fluid chamber.

3. The heat dissipation assembly according to claim 1, wherein the heat exchanger has a fluid channel, and the fluid channel is in a wavy shape.

4. The heat dissipation assembly according to claim 1, wherein the heat exchanger has a liquid chamber and an inner fin structure, and the inner fin structure is located in the liquid chamber.

5. The heat dissipation assembly according to claim 4, wherein the inner fin structure is in a sheet shape or a pin shape.

6. The heat dissipation assembly according to claim 1, wherein the heat exchanger has an outer surface and an outer fin structure, and the outer fin structure is disposed on the outer surface.

7. A motherboard module, comprising:
a motherboard, comprising a first heat source and a second heat source which has a thermal design power greater than a thermal design power of the first heat source; and
a heat dissipation assembly, comprising:
a heat exchanger, configured to be thermally coupled to the first heat source and receive a coolant, such that the coolant absorbs heat generated by the first heat source so as to have temperature increase; and
a cold plate, configured to be thermally coupled to the second heat source, wherein the cold plate is in fluid communication with the heat exchanger for receiving the coolant from the heat exchanger, such that the coolant absorbs heat generated by the second heat source so as to vaporize.

8. The motherboard module according to claim 7, wherein the first heat source comprises at least one of a voltage regulator chip, a network communication chip and a retimer chip, and the second heat source comprises at least one of a CPU and a GPU.

9. The motherboard module according to claim 7, further comprising a heater, wherein the heater is different from the first heat source and the second heat source.

10. The motherboard module according to claim 9, wherein the heat exchanger is thermally coupled to the heater, and the heater is configured to heat the coolant flowing into the heat exchanger when the coolant does not reach a predetermined temperature and stop heating the coolant flowing into the heat exchanger when the coolant reaches the predetermined temperature.

11. The motherboard module according to claim 7, further comprising a heater, wherein the heater is different from the first heat source and the second heat source, the heat exchanger is thermally coupled to the heater, and the heater is configured to heat the coolant flowing into the heat exchanger when the second heat source does not reach a predetermined temperature and stop heating the coolant flowing into the heat exchanger when the second heat source reaches the predetermined temperature

12. The motherboard module according to claim 7, wherein the motherboard further comprises a circuit board, the circuit board has a first surface and a second surface located opposite to each other, and the first heat source and the second heat source are disposed on the second surface of the circuit board.

13. The motherboard module according to claim 7, wherein the heat dissipation assembly further comprises a connection pipe, the motherboard further comprises a circuit board, the circuit board has a first surface and a second surface located opposite to each other, the first heat source and the second heat source are respectively disposed on the first surface and the second surface of the circuit board, the connection pipe penetrates through or bypasses the motherboard, and the cold plate is in fluid communication with the heat exchanger via the connection pipe.

14. The motherboard module according to claim 7, wherein the cold plate has a two-phase fluid chamber and a boiling enhancement structure, and the boiling enhancement structure is located in the two-phase fluid chamber.

15. The motherboard module according to claim 7, wherein the heat exchanger has a fluid channel, and the fluid channel is in a wavy shape.

16. The motherboard module according to claim 7, wherein the heat exchanger has a liquid chamber and an inner fin structure, and the inner fin structure is located in the liquid chamber.

17. The motherboard module according to claim 16, wherein the inner fin structure is in a sheet shape or a pin shape.

18. The motherboard module according to claim 7, wherein the heat exchanger has an outer surface and an outer fin structure, and the outer fin structure is disposed on the outer surface.

19. An electronic device, comprising:
a coolant distributing device, configured to output a coolant; and
a motherboard module, comprising:
a motherboard, comprising a first heat source and a second heat source which has a thermal design power greater than a thermal design power of the first heat source; and
a heat dissipation assembly, comprising:
a heat exchanger, configured to be thermally coupled to the first heat source and in fluid communication with the coolant distributing device, wherein the heat exchanger is configured to receive the coolant, such that the coolant absorbs heat generated by the first heat source so as to have temperature increase; and
a cold plate, configured to be thermally coupled to the second heat source, wherein the cold plate is in fluid communication with the heat exchanger and the coolant distributing device, and the cold plate is configured to receive the coolant from the heat exchanger, such that the coolant absorbs heat generated by the second heat source so as to vaporize, and the vaporized coolant flows back to the coolant distributing device.

20. The electronic device according to claim 19, further comprising a liquid pipe and a gas pipe, wherein the coolant distributing device comprises a container, a pump and a condenser, the container, the pump, the liquid pipe, the heat exchanger, the cold plate, the gas pipe and the condenser are sequentially connected one another so as to from a circulation loop for the coolant.

21. The electronic device according to claim 19, wherein the first heat source comprises at least one of a voltage regulator chip, a network communication chip and a retimer chip, and the second heat source comprises at least one of a CPU and a GPU.

22. The electronic device according to claim 19, wherein the motherboard module further comprises a heater, the heater is different from the first heat source and the second heat source, the heat exchanger is thermally coupled to the heater, and the heater is configured to heat the coolant flowing into the heat exchanger when the coolant does not reach a predetermined temperature and stop heating the coolant flowing into the heat exchanger when the coolant reaches the predetermined temperature.
